(19) United States
(12) Patent Application Publication
(10) Pub. No.: US 2026/0367374 A1
(43) Pub. Date: Nov. 19, 2026

(54) LIGHT-EMITTING DEVICE WITH IMPROVED EXTRACTION

(71) Applicants: CENTRE NATIONAL DE LA RECHERCHE SCIENTIFIQUE, PARIS (FR); UNIVERSITE PARIS-SACLAY, GIF-SUR-YVETTE (FR); INSTITUT D'OPTIQUE GRADUATE SCHOOL, PALAISEAU CEDEX (FR)

(72) Inventors: François BALEMBOIS, BOISSY LE SEC (FR); Pierre PICHON, PALAISEAU (FR)

(73) Assignees: CENTRE NATIONAL DE LA RECHERCHE SCIENTIFIQUE, PARIS (FR); UNIVERSITE PARIS-SACLAY, GIF-SUR-YVETTE (FR); INSTITUT D'OPTIQUE GRADUATE SCHOOL, PALAISEAU CEDEX (FR)

(21) Appl. No.: 19/136,385

(22) PCT Filed: Dec. 20, 2023
(86) PCT No.: PCT/EP2023/087057

§ 371 Date: Jun. 6, 2025

(30) Foreign Application Priority Data
Dec. 22, 2022 (FR) FR2214270

(51) Int. Cl. G02B 19/00; F21V 8/00

(52) U.S. Cl. CPC G02B 19/0009; G02B 6/0003; G02B 6/0055; G02B 19/0047

(57) ABSTRACT

A light-emitting device including: —a light concentrator made of a solid fluorescent or scintillation material with at least seven faces: two parallel faces referred to as large faces; and at least five faces referred to as side faces, including: —a first side face and a second side face having a surface greater than a surface of the other side faces; —a third side face, adjacent to the first side face and to the second side face; —a side face adjacent to the first side face and a side face referred to as the second facet adjacent to the second side face, the first facet and the second facet forming an angle α that is smaller than 175° and greater than 0°; —a first mirror arranged to cover the first facet; —a second mirror arranged to cover the second facet.

### TECHNICAL FIELD

The present invention relates to the field of concentrators pumped by external radiation and more particularly to the improvement of the extraction of light emitted within such a concentrator.

### BACKGROUND

Light-emitting diodes (LEDs) have many applications in lighting. However, LED luminance is limited to values not suitable for certain applications.

One solution for increasing LED luminance is to use LED-pumped luminescent concentrators (see, for example, Barbet, Adrien, et al. “Light-emitting diode pumped luminescent concentrators: a new opportunity for low-cost solid-state lasers.” Optica 3.5 (2016): 465-468.). This concentrator is, for example, a crystal that fluoresces in the visible (red-orange), like Ce:YAG, which absorbs in the blue (around 450 nm), at a wavelength where LEDs perform very well. The crystal is cut in the shape of a plane, lined with hundreds (if not thousands) of LEDs on the two large surfaces, and emitted from the edges. These concentrators deliver luminance values 10 to 20 times higher than those of LEDs.

FIG. 1A shows an example of a light-emitting module MEO known from the prior art, based on a concentrator crystal CL in the form of a parallelepiped of length L, width w, and thickness e. The MEO emission module comprises a set of LEDs designed to emit in a first spectral band and a light concentrator CL. The concentrator CL has at least one illumination face FE1, FE2, of dimensions L×w, illuminated by the electroluminescent radiation L_{d} emitted by the LEDs (optical pumping). The FE1 and FE2 illumination faces are also known as “large pumping faces”, as their surface area is greater than that of the concentrator's other faces, in order to maximize exposure to incident pump radiation (La). The exit face FS is chosen from the two smallest faces (here e×w). Isotropic emission means that the same amount of light is emitted on all faces. The smallest face therefore has the highest illumination. The concentrator effect is used to increase illumination and luminance. The structure therefore comprises two large pumping faces (FE1, FE2), two large side faces (FL1, FL2) and two small side faces, one of which is chosen as the exit face FS.

The concentrator crystal is configured to absorb electroluminescent radiation La. The luminous flux emitted by the LEDs and directed towards the illumination face is absorbed by the luminophores Lum of the fluorescent crystal, which are distributed throughout the volume of the crystal and then emit fluorescent radiation inside the crystal. Inside the concentrator, the rays emitted can be classified into two main categories:
trapped rays Lₚ: these rays are trapped in the crystal as a result of total internal reflection (TIR) on the various faces of the crystal. These rays exist, for example, if the concentrator is placed in the air and its shape is a parallelepiped with 6 faces parallel in pairs and perpendicular to each other, and if the concentrator's index is greater than √2. Trapped rays never leave the crystal, except for its imperfections.
untrapped rays are those that eventually leave the crystal. They can be divided into two sub-categories: guided rays L_{g}, which are guided by TIR and emerge on one of the concentrator's faces, and unguided rays Lₒᵤₜ, which exit directly from the concentrator without being reflected on the faces.

FIG. 1B shows the angular diagram of the rays emitted and trapped in the concentrator (a parallelepiped with 6 parallel faces, divided into pairs). The dark caps—also known as “exit cones” or “escape cones”—represent the angles corresponding to untrapped rays (guided and unguided) for each face of the concentrator, and the light areas represent the angles corresponding to rays trapped by total internal reflection within the concentrator. In this example, the medium chosen as the concentrator crystal CL is a Ce:YAG crystal (index n₂=1.82) with a critical angle of 33° when the ambient medium is air. This angle corresponds to the angle at the apex of the exit cone on the concentrator faces. The percentage of radiation trapped by TIR relative to untrapped radiation is determined by the crystal index and that of the ambient medium by Snell-Descartes law.

In the concentrator shown in FIG. 1A, assuming that the exit face is in contact with air (index n=1) and that the concentrator index is n=1.82 (e.g. YAG), only 8% of the fluorescence radiation passes through the exit face FS to form the exit beam Lₛ. The rest of the fluorescence radiation is trapped within the concentrator by total internal reflection (52%) or leaves the concentrator by exiting through the other faces (5×8%) (see FIG. 1B). In the case of a parallelepiped concentrator (n=2.4) in air, the percentage of trapped rays reaches 73%.

Luminescent concentrators are isotropic light sources with light exiting from all faces and in all directions. From a user's perspective, it's important to be able to collect light exiting from just one face. This is the exit face FS. The concentrator's extraction efficiency is defined by the ratio between the light power exiting from FS (the exit beam power Lₛ) and the total light power emitted by the concentrator.

Extraction efficiency in light-emitting media has been a crucial topic in the scintillation field for over 50 years (see for example M Ankenbrandt and E. M. Lent “Increasing the light collection efficiency of scintillation counters”, RSI Vol 34 No. 6 p647 (1963)). This subject is particularly important because of the high refractive index of scintillators (Ce:YAG n=1.83, BGO n=2.15), which results in a high percentage of light trapped by total internal reflection (52% for Ce:YAG, 65% for BGO in a parallelepiped geometry) and therefore low extraction efficiency

The problem of extraction efficiency is also of interest in the field of quantum optics for single-photon emission using diamonds with nitrogen-vacancy centers (N-V centers). In fact, diamonds have a high percentage of light trapped by total internal reflection (73% for a parallelepiped geometry), given their high index (n=2.4). This property limits the performance of the N-V center transmitter.

In order to increase extraction efficiency, it is known to the person skilled in the art to place a mirror on the side face opposite the exit face, as shown in FIG. 1C, referred to as the standard configuration. It is then possible to double the extraction efficiency compared with previous values (2×8%=16% for Ce:YAG and 2×4.5%=9% for diamond in a parallelepiped geometry) by coupling exit cones 1 and 2 using the mirror. However, this extraction efficiency remains very limited compared to the potential.

Another solution detailed in document EP21305827 and shown in FIG. 2A consists in modifying the concentrator of FIG. 1A by introducing a new face in the form of a beveled edge SA between two side faces defined as the exit face and crossed by the exit beam Lₛ. By judiciously adapting the normal of the edge SA, it is possible to “recycle” a significant portion of the rays that would have been trapped in the concentrator CL without the beveled edge SA, and direct them towards the exit face. Coupling between the cones is ensured by imaging the side faces, which are considered to be flat mirrors. Thus, the image of cone No. 1 by the vertical (respectively horizontal) side faces of FIG. 2B is cone No. 4 (respectively No. 2). FIG. 2B therefore shows that the exit cone has 3 prior reflections off the side faces of the structure (cones 1, 2 and 3). It is therefore theoretically possible to obtain an extraction efficiency 4 times greater than that shown in FIG. 1A. This configuration leads to an extraction efficiency of 4×8%=32% for Ce:YAG and 4×4.5%=18% for diamond in a parallelepiped geometry.

However, further improvements in extraction efficiency are still desirable.

The principle of the invention is to increase the number of cones coupled to the exit face by considering the reflections preceding the exit cone through multiple images on the side faces.

To this end, an object of the invention is a light-emitting device comprising:
a light concentrator made of a solid fluorescent or scintillation material comprising at least seven faces, two large parallel faces and at least five faces referred to as side faces, including a first side face and a second side face having a surface greater than a surface of the other side faces, an exit face adjacent to the first side face and the second side face, a first facet adjacent to the first side face and a facet adjacent to the second side face, the first facet and the second facet forming an angle α greater than 0 and less than 175°
a first mirror arranged to cover said first facet
a second mirror arranged to cover said second facet.

By carefully selecting the angle α between the first facet and the second facet, the concentrator makes it possible to couple the exit cone associated with the exit facet to other cones that exist in the reflective structure, so as to achieve a higher extraction efficiency than that of prior art solutions.

### SUMMARY

To this end, an object of the invention is a light-emitting device comprising:
a light concentrator in a solid fluorescent or scintillation material having an index n_{c} and adapted to absorb incident light and then emit luminescent radiation within said concentrator, said concentrator comprising at least seven faces, two parallel faces referred to as large faces, and at least five faces referred to as side faces, including:
a first side face and a second side face with a surface greater than a surface of the other side faces,
a third side face, referred to as exit face, adjacent to the first side face and the second side face, a portion, referred to as exit portion, of the rays of said luminescent radiation being guided by total internal reflection within the concentrator through said exit face
a side face referred to as first facet adjacent to the first side face and a side face referred to as second facet adjacent to the second side face,
a first mirror arranged to cover said first facet
a second mirror arranged to cover said second facet the first facet and the second facet forming an angle α greater than 0 and less than 175° so that a portion of the luminescent radiation, referred to as the recycled portion, passes through said exit face after at least one reflection on said first or second facet or on said first or second mirror, the exit portion and the recycled portion forming an exit beam.

According to one embodiment, the angle α is adapted according to the dimensions and an arrangement of the facets in order to maximize an extraction efficiency of the exit beam.

According to one embodiment, the angle α is between 95° and 160°.

According to one embodiment, the angle α is between 100° and 140°.

According to one embodiment, the angle α is between 100° and 120°.

According to one embodiment, the angle α is equal to 110° within +1°.

According to one embodiment, the concentrator comprises a number of side faces equal to 5, the first and second facets being adjacent.

According to one embodiment, the concentrator comprises a number of side faces equal to 6, including an additional facet adjacent to the first facet and the second facet.

According to one embodiment, the concentrator comprises a number of side faces greater than 6, including a plurality of additional facets, each additional facet being adjacent to two other additional facets, or adjacent to another additional facet and to the first facet, or adjacent to another additional facet and the second facet.

According to one embodiment, the large faces have a surface area greater than a surface area of the other faces.

According to one embodiment, the device comprises a first additional mirror arranged to cover said first side face and a second additional mirror arranged to cover said second side face. Preferentially, the first side face and the second side face are not parallel.

According to one embodiment, the index n_{c} of the concentrator is greater than 1.5, the device comprising an exit medium in contact with the exit face and having an index nₛ such that n_{c}>nₛ>1. Preferentially, the device comprises an optical system attached to the exit medium, adapted to collimate rays of the exit beam.

According to one embodiment, the device comprises a third additional mirror arranged to cover said exit face, and wherein the concentrator has a beveled edge between the exit face and the first side face so that a portion, the referred to as the additional recycled portion, of said trapped portion passes through said beveled edge forming what is referred to as an additional exit beam.

### BRIEF DESCRIPTION OF THE FIGURES

Further features, details and advantages of the invention will become apparent upon reading the description made with reference to the appended drawings given by way of example and which show, respectively:

FIG. 1A a schematic view of an example of a light-emitting module known from the prior art,

FIG. 1B, a representation of the angular diagram of rays emitted and trapped in the concentrator shown in FIG. 1A,

FIG. 1C a schematic view of an example of a light-emitting module known from the prior art,

FIG. 2A a schematic view of an example of a light-emitting module known from the prior art,

FIG. 2B, a schematic representation of spatial recycling in the concentrator shown in FIG. 2A,

FIG. 3A, FIG. 3B, a schematic perspective and top view respectively of a light-emitting device according to the invention,

FIG. 4, a graphical representation of the angular direction of the antecedents of the exit cone, generated by reflections in the structure, for three different angles between FT1 and FT2: α=169° (left graph), α=135° (center graph), α=99° (right graph)

FIG. 5, a graphical representation of the extraction efficiency as a function of the angle α of the concentrator of the invention, for three different values of concentrator index n_{c} (n_{c}=1.5, n_{c}=1.83 and n_{c}=2.4),

FIG. 6, a graphical representation of the extraction efficiency as a function of the angle α of the concentrator of the invention, for three different values of linear loss coefficient: 2×10⁻³ cm⁻¹ (top curve), 2×10⁻² cm⁻¹ (middle curve), 2×10⁻¹ cm⁻¹ (bottom curve),

FIG. 7, FIG. 8, a planisphere representation of the exit cones of the concentrator of the invention for α=120° and α=157.5° respectively,

FIG. 9, a schematic top view of a light-emitting device according to the invention wherein the first and second facets are adjacent and have different dimensions,

FIG. 10, a schematic top view of a light-emitting device according to the invention wherein the concentrator comprises a number of side faces equal to 6, including an additional facet adjacent to the first facet and the second facet,

FIG. 11, a schematic view of a preferred embodiment of the invention wherein the device comprises an exit medium in contact with the exit face having an index nₛ such that n_{c}>nₛ>1 and comprises a collimating optical system,

FIG. 12, a schematic view of one embodiment of the invention,

FIG. 13, a schematic view of one embodiment of the invention,

In the figures, unless otherwise indicated, the elements are not to scale and identical references designate identical elements.

### DETAILED DESCRIPTION

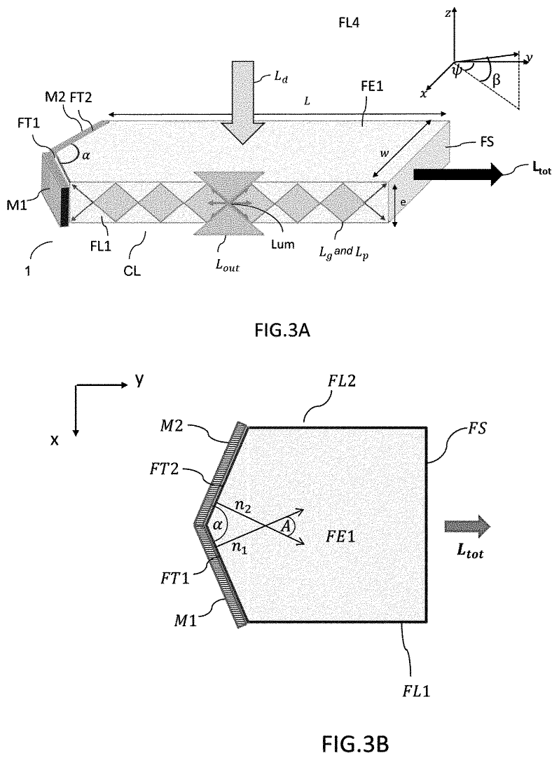

FIG. 3A shows a schematic perspective view of a light-emitting device 1 according to the invention. FIG. 3B shows a schematic top view in an xy plane of the light-emitting device 1 according to the invention.

The light-emitting device according to the invention comprises a light concentrator CL made from a solid fluorescent or scintillator material adapted to absorb incident light L_{d} causing the emission of luminescent radiation L_{L} within the concentrator.

The concentrator CL of the invention has an optimized geometry to optimize the extraction of luminescent radiation L_{L}.

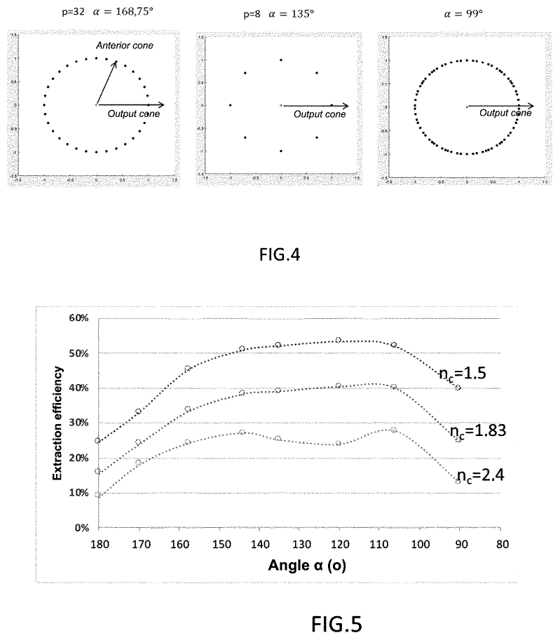

The concentrator has an index n_{c} preferentially greater than 1.5, as the geometry of the invention is particularly advantageous for high indices (see FIG. 4 described below).

The concentrator CL comprises at least seven faces, including two parallel faces called “large faces” or “illumination faces” FE1, FE2. Here and in the rest of the document, “parallel faces” means here that the faces are parallel to within ±5°. By way of example, in FIGS. 3A and 3B, the large faces FE1, FE2 have two main dimensions: a length L and a width w.

Preferentially, the large faces have a surface area greater than a surface area of the other faces, to maximize exposure to incident pumping radiation (L_{d}). This results in a higher-powered exit beam Lₛ.

The concentrator CL further comprises at least five so-called side faces, including a first side face FL1 and a second side face FL2. The side faces FL1, FL2 have a larger surface area than a surface area of the other side faces to ensure a concentration effect on the exit face, as explained above. By way of example, in FIGS. 2A and 2B, the side faces FL1, FL2 are rectangular and have dimensions e×L, where e is the thickness of the concentrator.

The concentrator CL comprises a third side face FS, known as the exit face, adjacent to the first side face FL1 and the second side face FL2. By way of example, in FIGS. 2A and 2B, the face FS is rectangular and has a dimension e×w.

Finally, the concentrator CL comprises two further side faces: a side face known as the first facet FT1 adjacent to the first side face and a side face known as the second facet FT2 adjacent to the second side face. The normals n₁, n₂ to the planes of the two facets FT1 and FT2 form an angle A between them (see FIG. 3B). The angle α between the facets is defined as α=180°−A. In the invention, this angle α is greater than 0° and less than 175°.

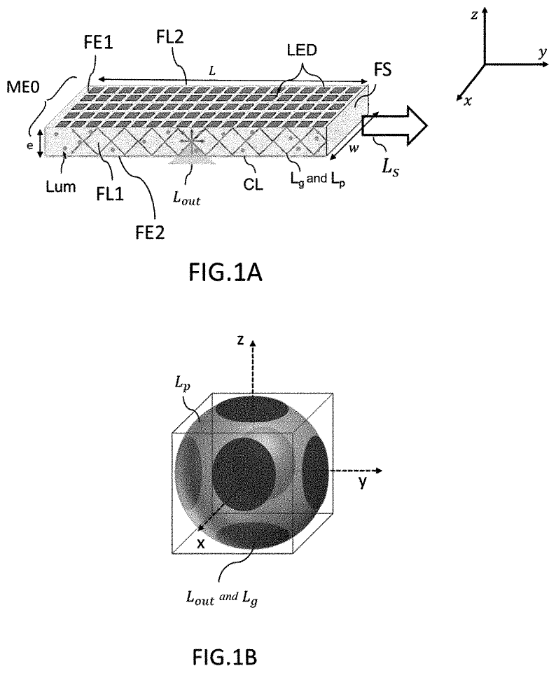

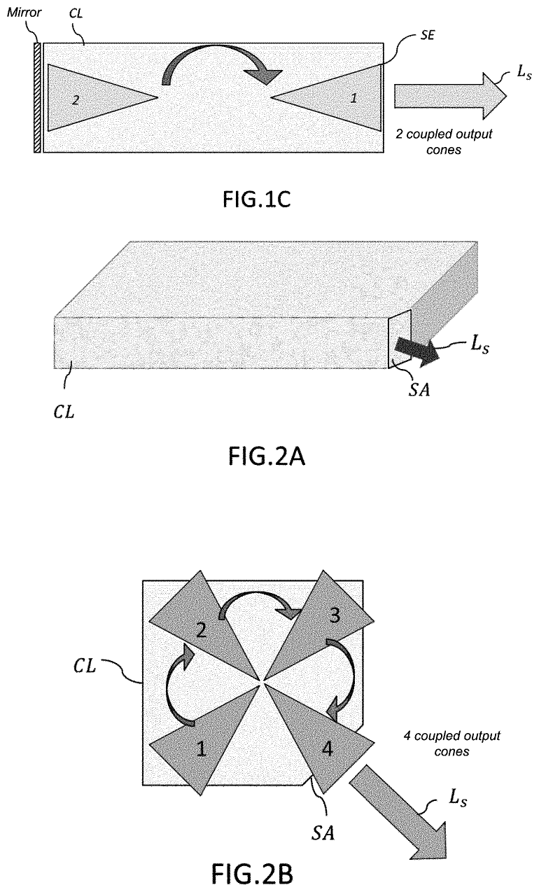

Note that the case α=180° (see FIG. 5, for example) does not correspond to an embodiment of the invention, but to the prior art configuration shown in FIG. 1C (“standard” configuration).

The device 1 further comprises a first mirror M1 arranged to cover the first facet FT1 and a second mirror M2 arranged to cover the second facet FT2.

A portion of the luminescent radiation L_{L}, known as the trapped portion Lₚ, is trapped by total internal reflection within the concentrator. A second portion is made up of light exiting the concentrator, with one part guided towards the edges L_{g} and one part Lₒᵤₜ exiting directly from the concentrator without reflecting off any of the faces. The exiting portion Lₛ refers to the rays of luminescent radiation L_{L} guided by total internal reflection within the concentrator through the exit face FS.

In addition, the portion of luminescent radiation passing through the exit face FS after at least one reflection on the first or second facet or on the first or second mirror is referred to as the recycled portion Lᵣ. The exit portion Lₛ and the recycled portion Lᵣ form the exit beam Lₜₒₜ.

Compared with the previous configurations (FIG. 1.A and FIG. 2B), the exit cone can be reflected on 4 faces (FL1, FL2, FT1, FT2) instead of one (FIG. 1.A) or three (FIG. 2B). The exit cone may therefore have more reflections on the side faces. In this way, more cones can be coupled to the exit, resulting in increased extraction efficiency.

Preferentially, the angle α is adapted according to the dimensions and an arrangement of the facets in order to maximize the extraction efficiency of the exit beam. Indeed, it is understood that the values of the angle α that maximize extraction efficiency depend directly on the geometry of the structure. As will be detailed later, for a given geometry, it is possible to calculate by simulation the angle values a that will enable this optimization.

FIG. 4 is a graphical representation of the angular direction of the antecedents of the exit cone, generated by reflections in the structure, for three different angles between FT1 and FT2: α=169° (left graph), α=135° (center graph), α=99° (right graph). To make the graph easier to read, FIG. 4 shows only the angular direction of the central axis of the cones under consideration. This is given by the straight line passing through the center of the circles and the points placed on the circle. In this way, each point on the graphs represents the axis of a cone, an antecedent of the exit cone.

As a non-limiting example, in the embodiment shown in FIGS. 3A and 3B, the side faces each have a normal in a plane parallel to said large faces. Also, all the cones considered in FIG. 4 have their central axis in the xy plane of the large faces. In fact, their images by the large faces are the cones themselves, since reflections by a mirror do not change the axis of the cones belonging to the plane of the mirror.

Furthermore, as a non-limiting example in the embodiment shown in FIGS. 3A and 3B, the dimensions of facets FT1 and FT2 are identical. We show that in the case where: α=π−π/p, with p an integer, the number of possible antecedents for the exit cone FS is finite and equals 2p−1. For example, for α=168.75°, we have p=16 and so there are 2p=32 antecedents of the exit cone. Depending on the value of the angle α, the images can be very numerous (as in the case α=99° shown in FIG. 4).

More generally, in a geometry different from that of the embodiment shown in FIGS. 3A and 3B, the number of antecedents is said to depend on the value of the angle α.

FIG. 5 is a graphical representation of the extraction efficiency as a function of the angle α of the concentrator of the invention, for three different values of concentrator index n_{c} (n_{c}=1.5, n_{c}=1.83 and n_{c}=2.4). FIG. 5 shows the results of Monte Carlo ray-tracing simulations to estimate the extraction efficiency of this coupling of rays to the exit cone.

The results shown in FIG. 5 are obtained for a concentrator with the geometry of the embodiment shown in FIGS. 3A and 3B, modified to include a first additional mirror arranged to cover said first side face FL1 and a second additional mirror arranged to cover said second side face FL2 (“optimized” configuration). These additional mirrors improve extraction efficiency.

As a non-limiting example, these results are presented assuming that the mirrors are totally reflective and for a concentrator with a linear loss coefficient equal to 2×10⁻³ cm⁻¹ for the central wavelength of the luminescence radiation.

FIG. 5 shows that extraction efficiency is significantly improved compared to the standard configuration for low linear loss conditions and perfect mirrors. These conditions are close to reality for a Ce:YAG concentrator (index n_{c}=1.83), which is a crystal with very low losses.

In addition, the extraction efficiency of the configuration shown in FIG. 5 is significantly improved over that of the prior art configuration shown in FIGS. 2A and 2B. As a reminder, the prior art configuration shown in FIGS. 2A and 2B achieves a maximum extraction efficiency of 4×8%=32% for Ce:YAG and 4×4.5%=18% for diamond. The configuration shown in FIG. 5 gives an extraction efficiency of 40% for Ce:YAG and 28% for diamond (index 2.4). We note that the improvement is relatively more significant when the concentrator index is high. This can be explained by the smaller the cone size, the higher the index.

The “bell shape” of the curves can be interpreted as follows:
for angles close to 180°, it's necessary to make a lot of to-and-fro in the structure to “turn the spokes” and couple a large number of spokes to the exit. There are two possible reasons for this. The first is linked to the angle of rotation of the ray at the exit of the reflection by the facets FT1, FT2, which is all the smaller the closer the angle α is to 180°. The second is that an angle α close to 180° will not allow the facets FT1, FT2 to combine their effects, as the rays will rarely intercept the facet FT2 after reflection against the facet FT1 (and vice versa). Thus, an angle α close to 180° implies long ray propagation distances before exiting the face FS, and therefore relatively higher losses.
for angle α=90°, the roof reflects a single direction with respect to the incident beam: the opposite direction. Thus, there are no multiple image effects for the exit cone.

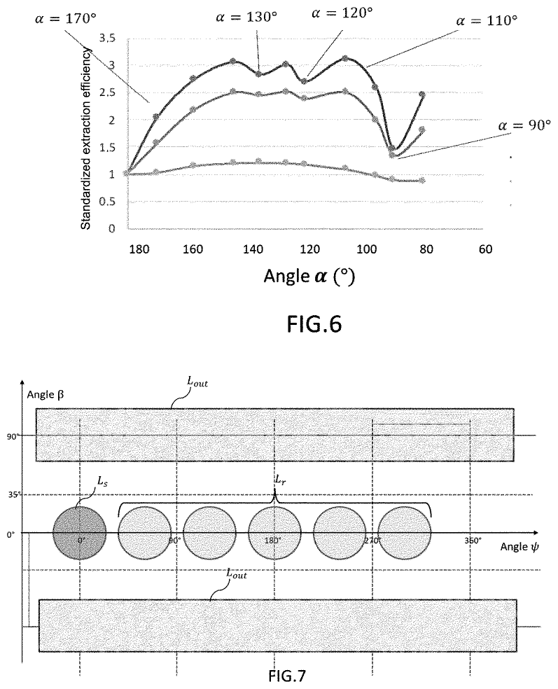

FIG. 6 is a graphical representation of the extraction efficiency as a function of the angle α of the concentrator of the invention, for three different values of linear loss coefficient: 2×10⁻³ cm⁻¹ (top curve), 2×10⁻² cm⁻¹ (middle curve), 2× 2×10⁻¹ cm⁻¹ (bottom curve).

FIG. 6 is obtained for the same configuration as FIG. 5 (“optimized configuration”) and for a diamond concentrator (index n_{c}=2.4), with extraction efficiency values normalized to the standard configuration.

FIG. 6 shows the fact that there is a very pronounced drop in extraction efficiency for an angle of 90°, and some local drops in configurations where few images are coupled onto the exit cone (angle of 120° or 130°). We can see that the best performances are obtained for angles close to 110° when losses are low in the structure. For larger losses (lower curves), the effects of local downturns diminish. As the average ray propagation distance is limited by losses, configurations requiring multiple reflections (and therefore long propagation distances) become less efficient in extraction.

Preferentially, the angle α is between 95° and 160° to optimize extraction efficiency. To further improve extraction efficiency, the angle α is between 100° and 140°. To further improve extraction efficiency, the angle α is between 100° and 120°. For maximum extraction efficiency, the angle α is preferentially equal to 110° within ±1°. By means of simulations, the inventors have determined that these angle α values are advantageous whatever the relative size of the facets or whatever the number of facets.

According to the simulations, the criterion for choosing the angle α appears to be fairly tolerant as long as the number of multiple images of the exit cone associated with the face FS is sufficient. This number of multiple images depends on the index of the medium and the value of the angle α.

To show this, FIGS. 7 and 8 are a planisphere representation of the exit cones using angular coordinates (ψ,β). β is the angle with respect to the z axis and w is the angle in the xy plane, with respect to the y axis. The white areas between the cones correspond to the trapped rays Lₚ. As a reminder, the angular portions Lₒᵤₜ correspond to the escape cones on the large faces FE1, FE2. The angular portion Lₛ corresponds to the exit cone associated with the face FS. Finally, the portion Lᵣ corresponds to the cones recycled by reflections on facets FT1, FT2, FL1, FL2 and exiting via the face FS. Without the faces FT1 and FT2, this light Lᵣ would not reach the exit face, it would exit via the side faces or remain trapped in the concentrator. The exit beam Lₜₒₜ is therefore composed of the portions Lₛ+L.

As a non-limiting example, FIGS. 7 and 8 are shown for the “optimized” configuration, with a diamond concentrator (index 2.4). FIG. 7 corresponds to the embodiment where α=120° and FIG. 8 corresponds to the embodiment where α=157.5°

In the embodiment shown in FIG. 7, for angle α=120°, the exit cone Lₛ has only 5 prior reflections. Given the high index of the concentrator, the critical angle associated with this exit cone is low and the cone Lₛ is small. In this case, the images of the outlet cone that form the recycled portion Lᵣ do not overlap, and extraction efficiency will be low. To choose the angle to maximize extraction efficiency, one criterion is the overlap of adjacent exit cone images Lₛ, the angle between two adjacent cone axes corresponding to the angle α at the apex of the exit cone.

Light can be extracted from a “corona”, corresponding to the overlap between the exit cone associated with the face FS and its images, as shown in FIG. 8. In fact, in the embodiment from FIG. 8, 16 escape cones are combined in the exit beam Lₜₒₜ. FIG. 8 shows that in this case, virtually the entire corona is extracted.

It is also possible to maximize extraction efficiency by using a shallower angle α to ensure rapid multiplication of rays and thus not be limited by propagation losses. Indeed, as shown in FIGS. 5 and 6, the extraction efficiency is best at an angle of around 110°. This solution covers the entire corona in just a few round-trips. With such an angle, the rays have 4 possibilities before returning to the exit face, depending on their position in the concentrator: They can reflect off FT1 only, off FT2 only or off a combination of FT1-FT2 or FT2-FT1.

Experimental proof of concept was carried out using a PMMA concentrator CL (n_{c} index=1.5) doped with an orange dye (lumogen, Evonics) with an optimized geometry. The results obtained show a 60% increase in exit power compared to a standard configuration for an angle α close to 120°. The loss coefficient estimated by simulation is 6×10⁻² cm⁻¹.

The concept of the invention has thus been validated, even though the experimental configuration is far from optimal, as the chosen medium has many losses (PMMA doped with a dye). Losses of the order of 10⁻³ cm⁻¹ can be obtained in well-understood crystals such as Ce:YAG. In this case, their performance will be even better, reaching the values shown in FIG. 5, tripling extraction compared with a standard configuration.

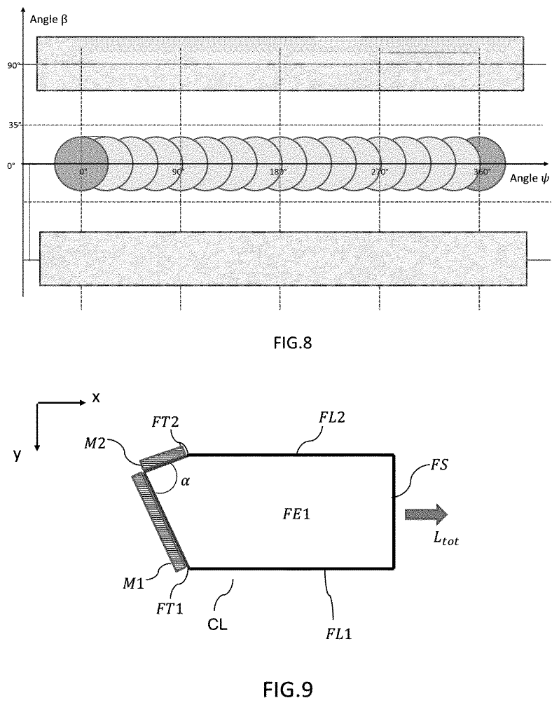

By way of non-limiting example, in the embodiment shown in FIGS. 3A and 3B, the concentrator comprises a number of side faces equal to 5, and the first facet FT1 and the second facet FT2 are adjacent and have identical dimensions. Alternatively, according to another embodiment shown in FIG. 9, the first and second facets are adjacent and have different dimensions. This has the advantage of making the structure less symmetrical and thus limiting trapped rays that could propagate through the concentrator without encountering the exit face at an angle belonging to the exit cone.

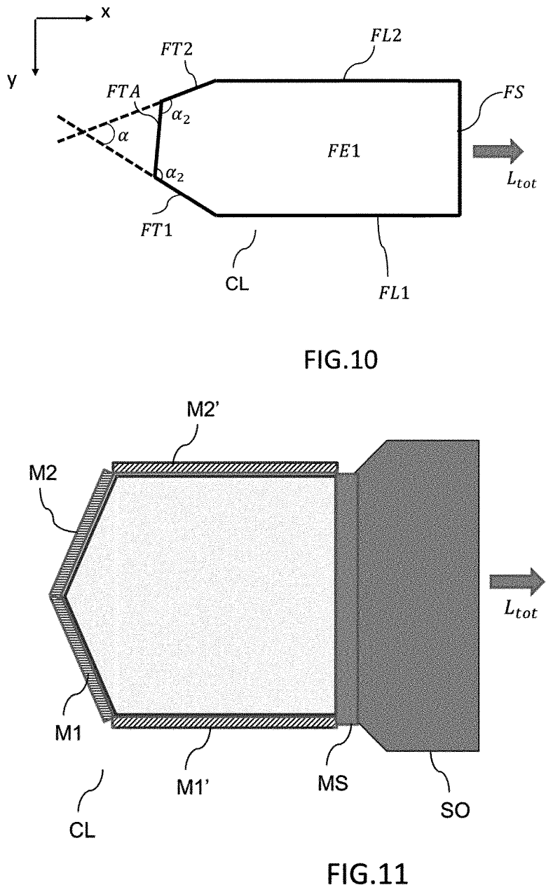

According to another embodiment shown in FIG. 10, the concentrator CL has a number of side faces equal to 6, including an additional facet FTA adjacent to the first facet FT1 and the second facet FT2. For clarity, the mirrors M1, M2 are not shown in FIG. 10, although they are included in the device 1. The facet FTA encourages a greater number of reflections of the rays from the Lᵣ portion and therefore a faster average exit of the rays through the face FS. The facet FTA therefore has the potential to increase extraction efficiency by reducing the propagation losses associated with the beam Lₒᵤₜ. As the angles α₁ and α₂ (defined in FIG. 10) are linked to a by the relationship α+π=α₁+α₂, it can be seen that it is always the angle α that conditions the extraction efficiency of the structure in the embodiment shown in FIG. 10.

According to another embodiment, the concentrator has a number of side faces greater than 6, including a plurality of additional facets. Each of these additional faces is adjacent to two other additional facets, or adjacent to another additional facet and to the first facet FT1 or adjacent to another additional facet and to the second facet FT2. Like the additional facet FTA in of the embodiment in FIG. 10, these additional facets can potentially increase extraction efficiency by reducing propagation losses associated with the beam Lₒᵤₜ.

According to an embodiment compatible with all recently discussed embodiments, the first side face FL1 and the second side face FL2 are not parallel. Depending on the angle α chosen, this non-parallelism makes it possible to increase the number of images of the exit cone produced by reflection on the side faces. This potentially increases extraction efficiency in cases where it is not maximized by the angle α.

In structures pumped by optical radiation L_{d}, the large pumping faces FE1, FE2 must remain freely accessible. What's more, in practice it's tricky to fit dichroic mirrors to these large FE1, FE2 faces, as they have to reflect multiple incidences and broad spectra with excellent coefficients (R>99.9%), while still transmitting pump radiation. Also, the escape cones Lₒᵤₜ on the large faces are irretrievable. Losses through these cones are index-related. Table 1 below shows that for high indices (n=1.83 or n=2.4, for example), the corona extracted from the air is far from the total potential (that is, all the rays emitted minus the two cones Lₒᵤₜ). In fact, the thickness of the corona is linked to the angle of the exit cone, which is also the angle of total internal reflection (θ_{TIR}).

TABLE 1

| | | | | |
|---|---|---|---|---|
| Index | 1.414 | 1.5 | 1.83 | 2.4 |
| Cone angle° (teta TIR) | 45.0 | 41.8 | 33.1 | 24.6 |
| Large-face losses | 29% | 25% | 16% | 9% |
| Air corona extraction | 71% | 67% | 55% | 42% |
| Glue corona extraction | | | n = 1.5 82% | n = 1.7 71% |
| Full corona extraction | 71% | 75% | 84% | 91% |

To increase this critical angle θ_{TIR}, it is preferable to use an exit medium with a higher index than air, when the concentrator index is high.

FIG. 11 shows a preferred embodiment of the invention wherein the device comprises an exit medium MS in contact with the exit face and having an index nₛ such that n_{c}>nₛ>1. According to the embodiment shown in FIG. 11, the device comprises a first additional mirror M1′ arranged to cover the first side face FL1 and a second additional mirror M2′ arranged to cover said second side face FL2. These mirrors M1′, M2′ are optional and increase extraction efficiency by preventing luminescence radiation from crossing the faces FL1, FL2 before exiting via the exit face FS (referred to as the optimized configuration).

The exit medium MS increases extraction efficiency by increasing the critical angle associated with the face exit cone FS, thus forming a wider exit cone. This is particularly useful when the concentrator index is high. This effect is shown in the row “Glue corona extraction” in Table 1, which shows the extraction efficiency of the configuration shown in FIG. 11. Compare this with the “Air corona extraction” line, which shows the extraction efficiency of the configuration shown in FIGS. 3A and 3B, with air as the exit medium. The extraction efficiency can be increased from 42% to 71% in a concentrator with index n_{c}=2.4 using an MS exit medium with index 1.7, for example.

Preferentially, as shown in FIG. 11, the device comprises an optical system SO attached to the exit medium, adapted to collimate rays of the exit beam Lₜₒₜ. The optical system SO is a non-imaging optical system that rectifies the rays leaving the exit medium MS and allows them to exit into the air. In this embodiment, the exit medium MS is, for example, an adhesive that provides a mechanical and optical link between the concentrator CL and the optical system SO.

Extraction will be limited by the glue index between the structure and the non-imaging optics. A glue with the same index as the medium of the optical system SO would be ideal, but high index glues (n>1.7) are hard to find these days.

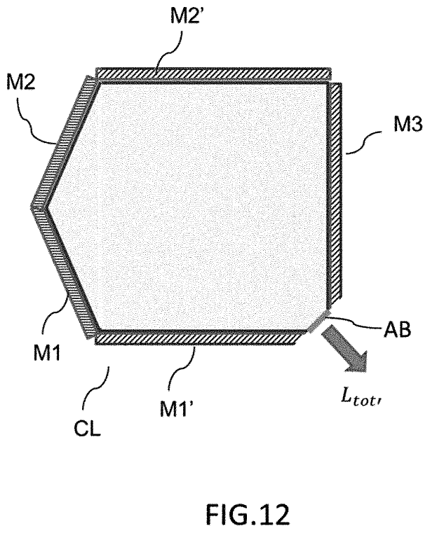

FIG. 12 schematically shows an embodiment of the invention wherein the device comprises:
a first additional mirror M1′ arranged to cover the first side face FL1,
a second additional mirror M2′ arranged to cover the second side face FL2
a third additional mirror M3 arranged to cover the exit face FS

In addition, the concentrator CL has a beveled edge AB between the exit face FS and the first side face FL1 (or the second side face FL2) so that a portion L_{r′} of the trapped portion Lₚ passes through the beveled edge AB. The rays of the portion L_{r′} form an additional exit beam L_{tot′}. In the configuration shown in FIG. 12, passage through the edge AB is the only way for the rays to exit the structure (excluding pumping faces). This forces the rays to reflect many times before they reach the right position and angle. This effect imposes a strong superposition of rays inside, which can be described as both angular and spatial recycling. The use of an edge AB increases propagation distance, and potentially reduces overall extraction, but increases luminance.

Preferentially, the normal of the beveled edge is parallel to the sum of the normals of the two side faces FL1, FS adjacent to the beveled edge at ±5°.

The embodiment of FIG. 11 and FIG. 12 can be combined.

That is, according to one embodiment of the invention, an exit medium MS is adjoined to the beveled edge AB to maximize the luminance of the additional exit beam L_{tot′} and maximize extraction efficiency.

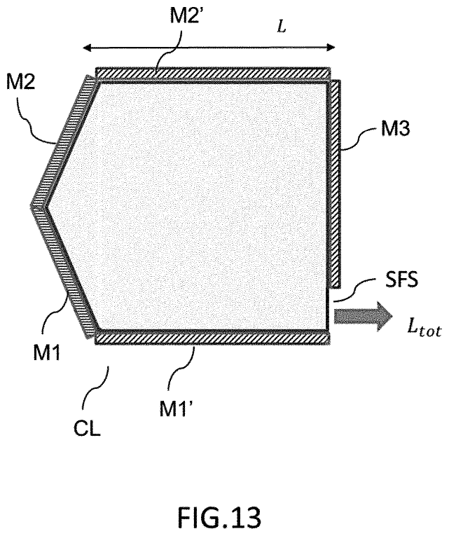

FIG. 13 schematically shows an embodiment of the invention wherein the device comprises:
a first additional mirror M1′ arranged to cover the first side face FL1,
a second additional mirror M2′ arranged to cover the second side face FL2
at least one additional mirror M3, arranged to partially cover the exit face FS, defining a surface SFS not covered by the mirror M3.

As previously explained, mirrors M1′, M2′ increase extraction efficiency by preventing luminescence radiation from crossing faces FL1, FL2 before exiting through the surface SFS.

The mirror M3, which partially covers the exit face, increases illuminance on the surface SFS. The dimensions of the emission module are adapted so that a ratio R=SFS/S_{SF} between the uncoated surface SFS and the surface of the face FS is adapted in such a way that rays of luminescent radiation reflect off M3 and propagate on average over an average distance L_{moy} »L within the concentrator CL before passing through the surface SFS. The luminescence rays leaving the concentrator form an exit beam Lₜₒₜ. L_{moy} »L means that L_{moy} is greater than 7 times, preferably 15 times L.

A ratio R adapted to verify the condition L_{moy} »L ensures that the effect of confining the rays in the 3 dimensions of space, that is, the luminescent radiation, instead of passing directly through the SFS surface after being generated, is mainly reflected within the concentrator CL and makes several round-trips on average within the concentrator CL before exiting through the SFS surface. The smaller the ratio R, the greater the average distance L_{moy} traveled by the luminescence rays within the concentrator CL before exiting. In this way, illuminance on the exit face is increased, as the luminescent radiation has time to “fill” the concentrator CL before exiting. The inventors have noticed that when the ratio R is less than or equal to ¼, or preferentially less than or equal to ⅛, the average distance L_{moy} is sufficient to achieve a consistent concentrator effect. Also, according to a preferred embodiment of the invention, the ratio R is less than or equal to ¼, or preferably less than or equal to ⅛.

The device structures detailed in the present description and figures are given by way of example and are intended to show the invention. They should in no way be considered as limiting the scope of the invention. Various modifications and variations of the described structures, manufacturing methods, and applications and uses thereof will be apparent to person skilled in the art without departing from the scope and spirit of the invention.

1.-15. (canceled)

16. A light-emitting device comprising:
a light concentrator in a solid fluorescent or scintillation material having an index n_{c} and adapted to absorb incident light and then emit luminescent radiation within said concentrator, said concentrator comprising at least seven faces, two parallel faces referred to as large faces, and at least five faces referred to as side faces including:
a first side face and a second side face with a surface greater than a surface of the other side faces,
a third side face, referred to as exit face, adjacent to the first side face and the second side face, a portion, referred to as exit portion, of the rays of said luminescent radiation being guided by total internal reflection within the concentrator through said exit face
a side face referred to as first facet adjacent to the first side face and a side face referred to as second facet adjacent to the second side face,
a first mirror arranged to cover said first facet,
a second mirror arranged to cover said second facet,
the first facet and the second facet forming an angle α greater than 0 and less than 175° so that a portion, of the luminescent radiation, referred to as recycled portion, passes through said exit face after at least one reflection on said first or second facet or on said first or second mirror, the exit portion and the recycled portion forming an exit beam.

17. The device according to claim 16, wherein said angle α is adapted as a function of the dimensions and an arrangement of the facets in order to maximize an extraction efficiency of the exit beam.

18. The device according to claim 16, wherein the angle α is between 95° and 160°.

19. The device according to claim 16, wherein the angle α is between 100° and 140°.

20. The device according to claim 16, wherein the angle α is between 100° and 120°.

21. The device according to claim 16, wherein the angle α is equal to 110° within ±1°.

22. The device according to claim 16, wherein the concentrator comprises a number of side faces equal to 5, the first and second facets being adjacent.

23. The device according to claim 16, wherein the concentrator comprises a number of side faces equal to 6, including an additional facet adjacent to the first facet and the second facet.

24. The device according to claim 16, wherein the concentrator comprises a number of side faces greater than 6, including a plurality of additional facets, each additional facet being adjacent to two other additional facets, or adjacent to another additional facet and to the first facet, or adjacent to another additional facet and the second facet.

25. The device according to claim 16, wherein the large faces have a surface area greater than a surface area of the other faces.

26. The device according to claim 16, comprising a first additional mirror arranged to cover said first side face and a second additional mirror arranged to cover said second side face.

27. The device according to claim 26, wherein the first side face and the second side face are not parallel.

28. The device according to claim 16, wherein the index ne of the concentrator is greater than 1.5, the device comprising an exit medium in contact with the exit face and having an index nₛ such that n_{c}>nₛ>1.

29. The device according to claim 28, comprising an optical system attached to the exit medium adapted to collimate rays of the exit beam.

30. The device according to claim 26, wherein the device comprises a third additional mirror arranged so as to cover said exit face, and wherein the concentrator has a beveled edge between the exit face and the first side face so that a portion, called additional recycled portion, of said trapped portion passes through said beveled edge forming a so-called additional exit beam.
